(19) United States
(12) Patent Application Publication
(10) Pub. No.: US 2023/0091379 A1
(43) Pub. Date: Mar. 23, 2023

(54) FIRST LEVEL INTERCONNECT UNDER BUMP METALLIZATIONS FOR FINE PITCH HETEROGENEOUS APPLICATIONS

(71) Applicant: Intel Corporation, Santa Clara, CA (US)

(72) Inventors: Liang HE, Chandler, AZ (US); Yeasir ARAFAT, Chandler, AZ (US); Jung Kyu HAN, Chandler, AZ (US); Ali LEHAF, Phoenix, AZ (US); Gang DUAN, Chandler, AZ (US); Steve S. CHO, Chandler, AZ (US); Yue DENG, Chandler, AZ (US)

(21) Appl. No.: 17/482,275

(22) Filed: Sep. 22, 2021

(51) Int. Cl. H01L 23/00; H01L 23/498; H01L 23/532; H01L 23/528

(52) U.S. Cl. CPC H01L 24/14; H01L 23/49811; H01L 23/53204; H01L 23/528

(57) ABSTRACT

Embodiments disclosed herein include electronic packages with first level interconnects that comprise a first layer. In an embodiment, the electronic package comprises a package substrate and a pad on the package substrate. In an embodiment, the pad comprises copper. In an embodiment, a first layer is over the pad. In an embodiment, the first layer comprises iron. In an embodiment, a solder is over the first layer, and a die is coupled to the package substrate by the solder.

### TECHNICAL FIELD

Embodiments of the present disclosure relate to electronic packages, and more particularly to electronic packages with fine pitch first level interconnect (FLI) under bump metallizations (UBMs) that significantly reduce intermetallic compound (IMC) growth.

### BACKGROUND

Interconnect stacks typically comprise a copper pad with a barrier layer over the copper pad. The barrier layer may sometimes be referred to as an under bump metallization (UBM) since the barrier layer is below a solder bump. Typically, the barrier layer is a material that prevents the interdiffusion of the copper with the solder (which generally comprises tin). Without the barrier layer, fast reaction kinetics between the copper and the solder result in the interdiffusion of copper and the solder. The reaction of copper and solder leads to the formation of intermetallic compounds (IMCs). IMCs are generally more brittle and have less desirable electrical properties than solder. When the percentage of IMC grows too large problems with electrical and mechanical integrity arise.

Currently, barrier layers may comprise nickel. However, nickel may no longer be a suitable material due to bump pitch scaling and reductions in the thicknesses of metal stacks. Particularly, in fine pitch first level interconnect (FLI) architectures (e.g., with a bump pitch of 25 μm and below) the thickness of the barrier layer may be reduced to the point where the nickel barrier layer is entirely consumed, and the solder is fully converted to an IMC. Additionally, fast IMC formation is detrimental to the electromigration performance of the package. So slower IMC formation kinetics is beneficial to any bump pitch.

### BRIEF DESCRIPTION OF THE DRAWINGS

FIG. 1A is a cross-sectional illustration of an interconnect with a nickel barrier layer, in accordance with an embodiment.

FIG. 1B is a cross-sectional illustration of a microstructure of an interconnect, where the nickel and solder has formed a thick intermetallic compound (IMC) layer, in accordance with an embodiment.

FIG. 2A is a cross-sectional illustration of an interconnect with a barrier layer that comprises iron, in accordance with an embodiment.

FIG. 2B is a cross-sectional illustration of a microstructure of an interconnect where the barrier layer and the solder form a thin IMC layer, in accordance with an embodiment.

FIG. 3A is a graph of IMC thickness versus reflow time at a reflow temperature that results in the solder being in a liquid phase, in accordance with an embodiment.

FIG. 3B is a graph of IMC thickness versus baking time at a temperature that results in the solder being in a solid phase, in accordance with an embodiment.

FIG. 3C is a graph of the barrier layer consumption versus time for various baking/reflow temperatures, in accordance with an embodiment.

FIG. 4A is a cross-sectional illustration of a plurality of pads that are on a package substrate or a die, in accordance with an embodiment.

FIG. 4B is a cross-sectional illustration of the structure after a solder resist layer is disposed over the pads, in accordance with an embodiment.

FIG. 4C is a cross-sectional illustration of the structure after solder resist openings are formed to expose the pads, in accordance with an embodiment.

FIG. 4D is a cross-sectional illustration of the structure after a barrier layer is disposed over the pads, in accordance with an embodiment.

FIG. 4E is a cross-sectional illustration of the structure after a solder is disposed over the barrier layers, in accordance with an embodiment.

FIG. 5A is a cross-sectional illustration of an electronic package with first level interconnects (FLIs) that comprise a barrier layer that comprises iron, in accordance with an embodiment.

FIG. 5B is a cross-sectional illustration of an electronic package with a bridge that electrically couples a first die to a second die, where the FLIs comprise a barrier layer that comprises iron, in accordance with an embodiment.

FIG. 6 is a cross-sectional illustration of an electronic system with FLIs that comprise a barrier layer that comprises iron, in accordance with an embodiment.

FIG. 7 is a schematic of a computing device built in accordance with an embodiment.

### EMBODIMENTS OF THE PRESENT DISCLOSURE

Described herein are electronic packages with fine pitch first level interconnect (FLI) under bump metallizations (UBMs) that significantly reduce intermetallic compound (IMC) growth, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

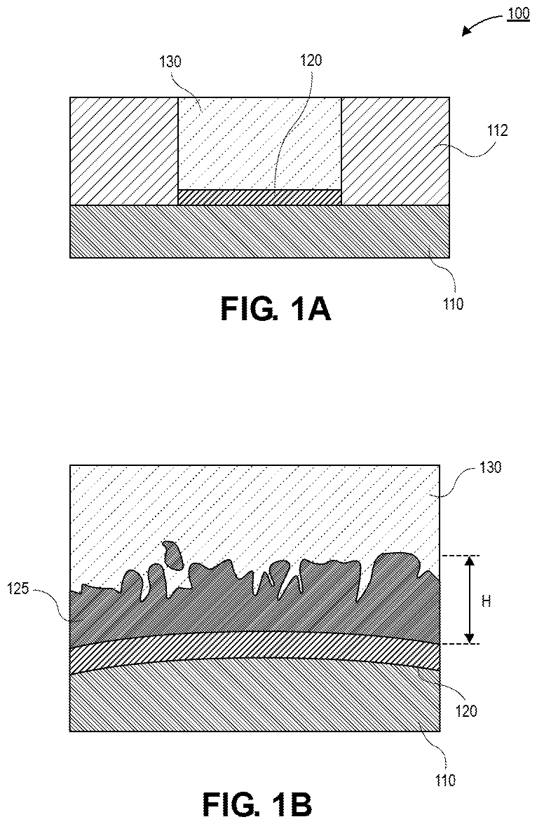

As noted above, first level interconnects (FLIs) may include an under bump metallization (UBM) or barrier layer that comprises nickel. The nickel barrier layer is between a pad (e.g., a pad comprising copper) and a solder (e.g., a solder comprising tin). An example of such a structure is shown in FIG. 1A.

Referring now to FIG. 1A, a cross-sectional illustration of an interconnect 100 is shown. The interconnect 100 may include a pad 110. The pad 110 is a conductive material, such as, but not limited to, a material comprising copper. A solder resist 112 or other dielectric or resist layer may be disposed over the pad 110. An opening through the solder resist 112 exposes a portion of the pad 110. In some instances a barrier layer 120 is plated over the exposed portions of the pad 110. Typically, the barrier layer 120 may comprise nickel. A solder 130 (e.g., a solder containing tin) is disposed over the barrier layer 120.

As the pitch of the pad 110 relative to other pads (not shown) is decreased, the thickness of the barrier layer 120 also decreases. In instances where the pads 110 have a fine pitch (e.g., approximately 25 μm or smaller), the barrier layer 120 may have a thickness that is approximately 2 μm or smaller. At such small thicknesses, the barrier layer 120 may be entirely consumed during reflow and/or baking processes. As used herein, “approximately” may refer to a value that is within 10% of the stated value. For example, “approximately 2 μm” may refer to a range between 1.8 μm and 2.2 μm.

Referring now to FIG. 1B, a cross-sectional illustration of a microstructure of an interconnect is shown. The interconnect illustrated may have been subject to one or more reflows. As such, a reaction between the solder 130 and the barrier layer 120 may have occurred as a result of diffusion. As shown, an intermetallic compound (IMC) 125 has formed at the interface between the solder 130 and the barrier layer 120. In the case of a nickel barrier layer 120 and a tin based solder 130, the IMC 125 may comprise Ni and Sn. For example, the IMC 125 may comprise Ni3Sn4. As shown, the IMC 125 has a jagged growth front into the solder 130. However, a maximum depth H into the solder 130 may be approximately 3 μm or greater. In some instances, the growth of the IMC 125 may consume the entire nickel barrier layer 120 and/or the entire solder 130. For instance, in FIG. 1B, the barrier layer 120 may have originally been approximately 2 μm thick, and has been reduced to a thickness of approximately 1 μm. It is to be appreciated that further reflows and/or baking may result in the complete consumption of the barrier layer 120. After consumption of the barrier layer 120, the pad 110 is exposed and additional diffusion may occur so that copper contributes to further IMC formation as well.

Accordingly, embodiments disclosed herein include barrier layers that comprise materials that reduces the formation of IMC at the interface between the solder and the barrier layer. The reduction in IMC growth minimizes the consumption of the barrier layer and the pad is protected. Additionally, the slower reaction rate reduces the amount of the solder that is converted to IMC material. As such, the electrical and mechanical properties of the interconnect are improved.

In a particular embodiment, the barrier layer comprises iron. The iron may be alloyed with another element. For example, the barrier layer may comprise iron and cobalt (FeCo) or iron and nickel (FeNi). As will be described in greater detail below, the reaction kinetics for material such as FeCo or FiNi and solder are greatly reduced compared to that of nickel and solder. As such, the growth of the IMC is minimal, as is the consumption of the barrier layer and the solder.

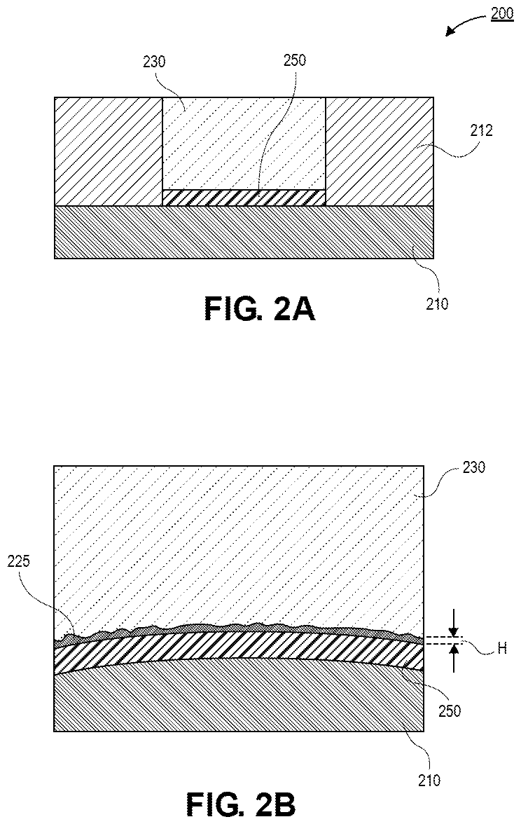

Referring now to FIG. 2A, a cross-sectional illustration of an interconnect 200 is shown, in accordance with an embodiment. The interconnect 200 may include a pad 210. The pad 210 is a conductive material, such as, but not limited to, a material comprising copper. A solder resist 212 or other dielectric or resist layer may be disposed over the pad 210. An opening through the solder resist 212 exposes a portion of the pad 210. In some instances a barrier layer 250 is plated over the exposed portions of the pad 210. In an embodiment, the barrier layer 250 may comprise iron. For example, the barrier layer 250 may comprise iron and cobalt (e.g., FeCo), or the barrier layer 250 may comprise iron and nickel (e.g., FeNi). A solder 230 (e.g., a solder containing tin) is disposed over the barrier layer 250.

As the pitch of the pad 210 relative to other pads (not shown) is decreased, the thickness of the barrier layer 250 also decreases. In instances where the pads 210 have a fine pitch (e.g., approximately 25 μm or smaller), the barrier layer 250 may have a thickness that is approximately 2 μm or smaller. Despite such a small thickness, the barrier layer 250 may persist through reflow and/or baking processes. That is, the barrier layer 250 may be present in a cross-section of the interconnect of a product available on the market.

Referring now to FIG. 2B, a cross-sectional illustration of a microstructure of an interconnect is shown, in accordance with an embodiment. It is to be appreciated that the microstructure in FIG. 2B and the microstructure in FIG. 1B both were subjected to the same reflow regime, and the microstructures are shown at the same scale. As such, direct comparisons between the two Figures can be made.

As shown, a reaction between the solder 230 and the barrier layer 250 may have occurred as a result of diffusion. As shown, an IMC 225 has formed at the interface between the solder 230 and the barrier layer 250. In the case of an iron and cobalt barrier layer 250 and a tin based solder 320, the IMC 225 may comprise Fe and Sn. For example, the IMC 225 may comprise FeSn₂. As shown, the IMC 225 has a relatively smooth growth front into the solder 230. In contrast to the case shown in FIG. 1B, a maximum depth H into the solder 230 is minimal. In some embodiments, the depth H may be approximately 1 μm or less, or approximately 0.5 μm or less. It is to be appreciated that the depth H is largely dependent on the thermal cycles the package experiences. However, it is to be appreciated that for a given set of thermal cycles, the depth H of an iron and cobalt barrier layer or an iron and nickel barrier layer will be smaller than the depth H of a nickel barrier layer. As will be shown in the following graphs, the growth rate of the IMC 225 in FIG. 2B may be approximately ten times slower than the growth rate of the IMC 125 in FIG. 1B.

Additionally, due to the slower reaction rate, the consumption of the barrier layer 250 is also reduced. For instance, in FIG. 2B, the barrier layer 250 may have originally been approximately 2 μm thick, and still maintains substantially the same thickness after a plurality of reflows. As such, the barrier layer 250 remains over the pad 210 and prevents the diffusion and reaction between the copper pad 210 and the solder 230.

It is to be appreciated that an original stack-up comprising a pad 210 (e.g., a copper pad), a barrier layer 250 (e.g., an iron containing barrier layer), and a solder 230 (e.g., a tin based solder) may result in the formation of a stack-up that includes an IMC 225. That is, in a production device available on the market, the structure may include an IMC 225 in some embodiments. The IMC 225 may comprise constituents of the barrier layer and of the solder. For example, the IMC 225 may have a composition of FeSn₂, as described above. However, the IMC 225 may also have additional constituents sourced from the solder. That is, the IMC 225 may include more elemental constituents than just those in the barrier layer and the Sn from the solder. Additionally, it is to be appreciated that the growth of the IMC 225 will not result in a layer with a uniform thickness. While smoother than the growth front in FIG. 1B, the growth front of the IMC 225 may be wavy. That is, the interface between the IMC 225 and the solder 230 may not be a straight plane, similar to the case when a material is plated over an underlying material.

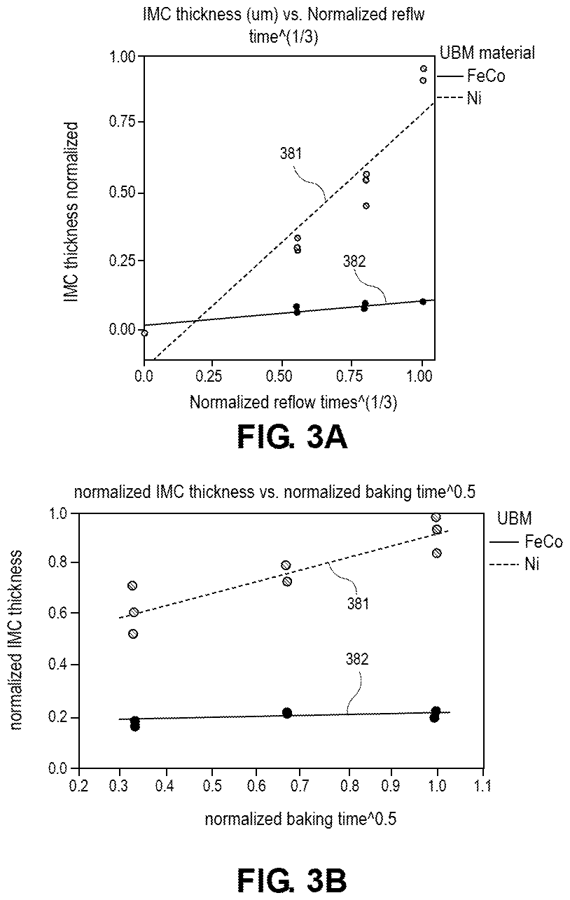

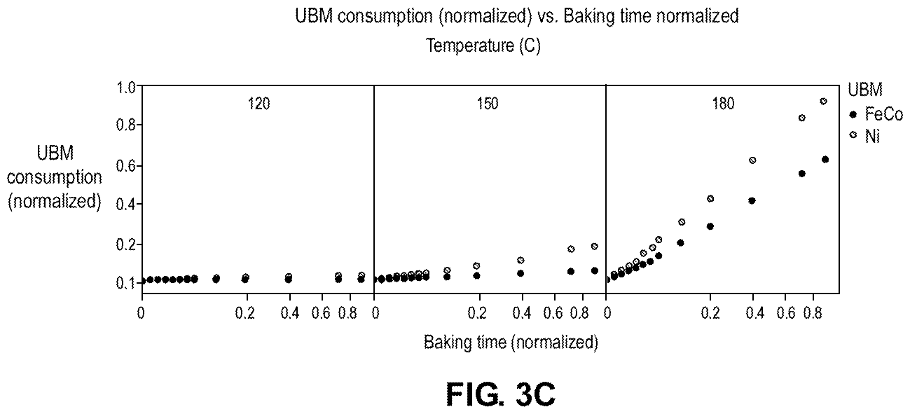

Referring now to FIG. 3A, a graph of IMC thickness versus time for an FeCo barrier layer and a Ni barrier layer is shown, in accordance with an embodiment. While FeCo is specifically shown in FIG. 3A and the following graphs, it is to be appreciated that other alloys comprising iron (e.g., FeNi) may also have similar trends. In FIG. 3A, the vertical axis is the normalized IMC thickness, and the horizontal axis is the cubed root of the normalized reflow time. The temperature of the reflow in FIG. 3A may be sufficient to provide a solder that is in a liquid phase. As shown, the trend line 381 of the IMC growth rate for the Ni barrier layer is significantly steeper than the trend line 382 of the IMC growth rate for the FeCo barrier layer. In an embodiment, the trend line 381 has a slope that is approximately ten times greater than the slope of the trend line 382 of the FeCo barrier layer. As such, in the case of diffusion with a liquid solder, the growth rate of IMC on a FeCo barrier layer is ten times slower than the growth rate of IMC on a Ni barrier layer.

Referring now to FIG. 3B, a graph of IMC thickness versus time for an FeCo barrier layer and a Ni barrier layer is shown, in accordance with an additional embodiment. In FIG. 3B, the vertical axis is the normalized IMC thickness, and the horizontal axis is the square root of the normalized bake time. The temperature of the bake in FIG. 3B may be low enough that the solder does not reflow. That is, the solder remains in a solid state in the embodiments shown in FIG. 3B. As shown, the trend line 381 of the IMC growth rate for the Ni barrier layer is steeper than the trend line 382 of the IMC growth rate for the FeCo barrier layer. In an embodiment, the trend line 381 has a slope that is approximately three times greater than the slope of the trend line 382 of the FeCo barrier layer. As such, in the case of solid state diffusion, the growth rate of IMC on a FeCo barrier layer is three times slower than the growth rate of IMC on a Ni barrier layer.

Referring now to FIG. 3C, an additional graph is shown that illustrates the amount of the barrier layer (UBM) that is consumed during various temperature bakes. For example, bakes at 120° C., 150° C., and 180° C. are shown. The vertical axis is the normalized amount of barrier layer consumption, and the horizontal axis is the normalized bake time. At all temperatures the amount of barrier layer consumption is lower for the FeCo barrier layer, compared to the Ni barrier layer. As the bake temperature increases, the spread between the barrier layer consumption of the Ni barrier layer and the FeCo barrier layer also increases. That is, for higher temperatures, the FeCo barrier layer provides a more significant benefit. Additionally, for a given temperature, the FeCo barrier layer provides a greater benefit (i.e., lower barrier layer consumption) at longer baking durations.

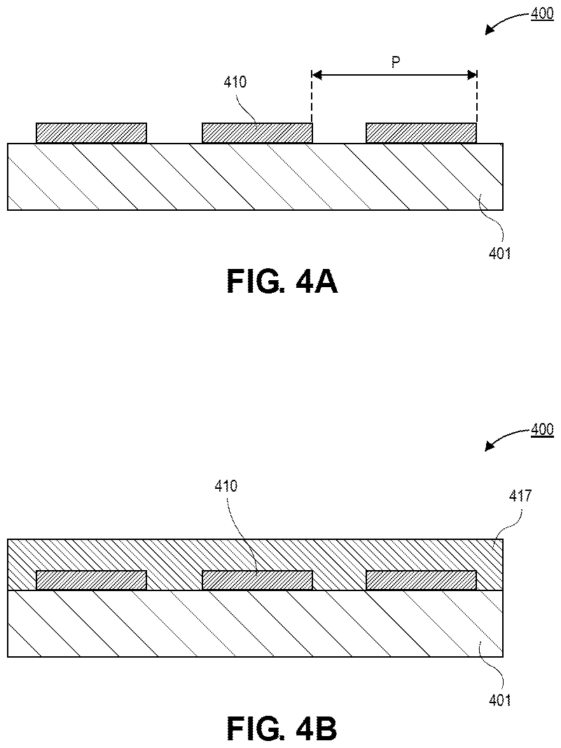

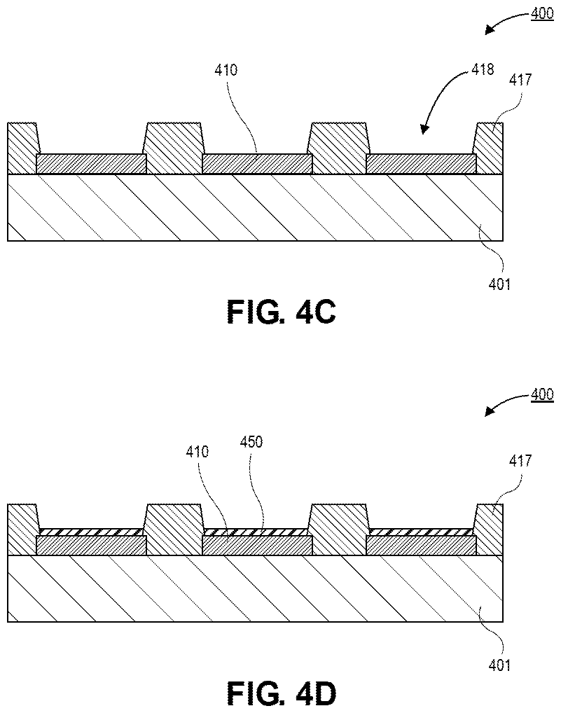

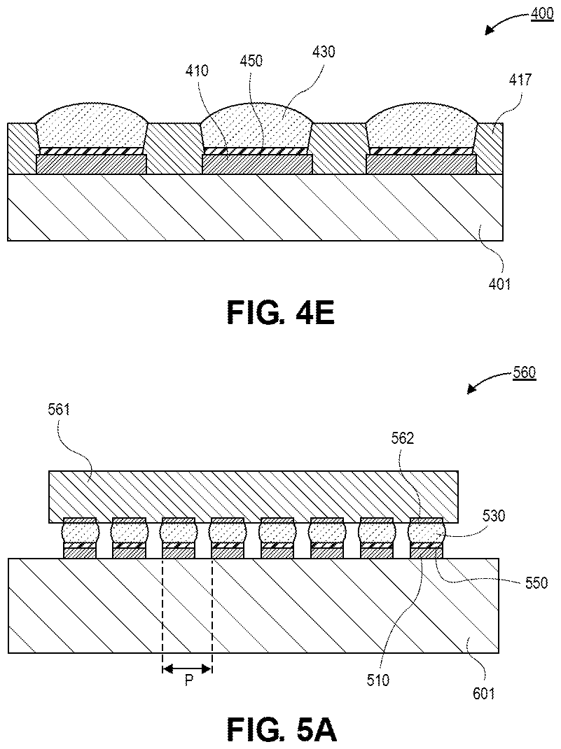

Referring now to FIGS. 4A-4D, a series of illustrations depicting a process for assembling an interconnect with an iron containing barrier layer (e.g., FeCo or FeNi) is shown, in accordance with an embodiment. The process shown in FIGS. 4A-4D is exemplary in nature. It is to be appreciated that many different process flows may be used in order to provide a structure with a pad, a barrier layer over the pad, and a solder over the barrier layer.

Referring now to FIG. 4A, a cross-sectional illustration of an electronic package 400 is shown, in accordance with an embodiment. In an embodiment, the electronic package 400 comprises a package substrate 401. The package substrate 401 may be an organic package substrate. That is, the package substrate 401 may comprise a plurality of laminated dielectric layers with conductive routing (not shown) embedded therein. The package substrate 401 may also comprise a core, a glass layer, or any other materials typical of electronic packaging architectures.

In an embodiment, a plurality of pads 410 are provided over a surface of the package substrate 401. The pads 410 may be a conductive material. For example, the pads 410 may comprise copper or the like. In an embodiment, the pads 410 are FLI pads. That is, the pads 410 may be used to connect the package substrate 401 to a die (not shown). In an embodiment, the pads 410 have a fine pitch P. For example, the pitch P may be approximately 25 μm or less.

Referring now to FIG. 4B, a cross-sectional illustration of the electronic package 400 after a solder resist 417 is disposed over the pads 410 is shown, in accordance with an embodiment. In an embodiment, the solder resist 417 may be a dielectric layer. The solder resist 417 may be laminated over a surface of the package substrate 401 and the pads 410. In some embodiments, the solder resist 417 covers sidewalls and the top surface of each of the pads 410.

Referring now to FIG. 4C, a cross-sectional illustration of the electronic package 400 after solder resist openings 418 are formed into the solder resist 417 is shown, in accordance with an embodiment. In an embodiment, the solder resist 417 may be patterned with a laser or other patterning process. For example, sidewalls of the openings 418 may be tapered in some embodiments. In an embodiment, the solder resist openings 418 may expose a portion of the top surface of the pads 410. That is, in some embodiments the entire top surface of the pads 410 may not be exposed. However, in other embodiments, the entire top surface of the pads 410 may be exposed.

Referring now to FIG. 4D, a cross-sectional illustration of the electronic package 400 after a barrier layer 450 is deposited is shown, in accordance with an embodiment. In an embodiment, the barrier layer 450 may have a thickness that is approximately 1 μm thick or greater. In an embodiment, the barrier layer 450 may comprise iron. In a particular embodiment, the barrier layer 450 comprises iron and cobalt (e.g., FeCo) or iron and nickel (e.g., FeNi). As noted above the iron containing barrier layer 450 may be chosen in order to minimize the growth of IMC at the interface between the barrier layer 450 and the solder (added in a subsequent processing operation).

In an embodiment, the barrier layer 450 may be deposited with a plating process or the like. That is, the barrier layer 450 may deposit up from the surface of the pads 410. In embodiments where the entire top surface of the pad 410 is not exposed by the solder resist opening 418, the barrier layer 450 may only cover the exposed portions of the pad 410 and not the entire top surface of the pad 410. Additionally, the barrier layer 450 may be conformal to the sidewalls of the solder resist opening 418. As such, sidewalls of the barrier layer 450 may be tapered in some embodiments.

Referring now to FIG. 4E, a cross-sectional illustration of the electronic package 400 after a solder 430 is applied over the barrier layer 450 is shown, in accordance with an embodiment. In an embodiment, the solder 430 may comprise tin. The solder 430 may minimally react with the barrier layer 450 in order to form an IMC. While not shown in FIG. 4E, it is to be appreciated that after one or more reflow or baking operations, an IMC may develop at the interface between the barrier layer 450 and the solder 430. The IMC may be substantially similar to the IMC 225 described in greater detail above with respect to FIG. 2B. That is, an IMC with a thickness of approximately 1 μm or smaller, or approximately 0.5 μm or smaller may be provided between the barrier layer 450 and the solder 430. It is to be appreciated that the thickness of the IMC is largely dependent on the thermal cycles the package experiences. However, it is to be appreciated that for a given set of thermal cycles, the IMC thickness of an iron and cobalt barrier layer or an iron and nickel barrier layer will be smaller than the IMC thickness of a nickel barrier layer. In an embodiment, the IMC may comprise iron and tin, though other constituents may also be present in the IMC, depending on the composition of the barrier layer 450 and the solder 430.

While referred to as a package substrate 401, it is to be appreciated that similar benefits may also accrue with pads on the die side. That is the barrier layer may be disposed over a die side pad as well. For example, a pad on the die may have a barrier layer 450 in order to mitigate IMC formation from the die side.

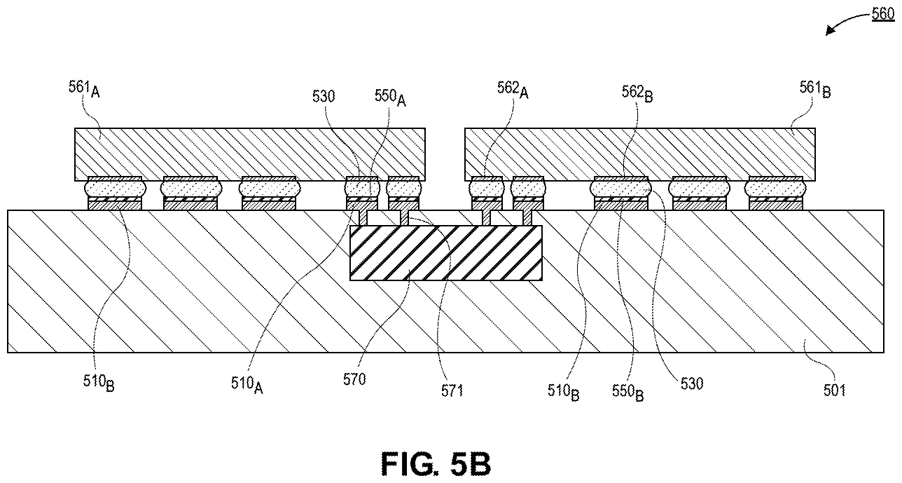

Referring now to FIG. 5A, a cross-sectional illustration of an electronic package 560 is shown, in accordance with an embodiment. In an embodiment, the electronic package 560 comprises a package substrate 501. The package substrate 501 may be an organic package substrate. That is, the package substrate 501 may comprise a plurality of laminated dielectric layers with conductive routing (not shown) embedded therein. The package substrate 501 may also comprise a core, a glass layer, or any other materials typical of electronic packaging architectures.

In an embodiment, a plurality of pads 510 are provided over a surface of the package substrate 501. The pads 510 may be a conductive material. For example, the pads 510 may comprise copper or the like. In an embodiment, the pads 510 are FLI pads. That is, the pads 510 may be used to connect the package substrate 501 to a die 561. In an embodiment, the pads 510 have a fine pitch P. For example, the pitch P may be approximately 25 μm or less.

In an embodiment, a barrier layer 550 is provided over a top surface of the pads 510. In an embodiment, the barrier layer 550 may have a thickness that is approximately 1 μm thick or greater. In an embodiment, the barrier layer 550 may comprise iron. In a particular embodiment, the barrier layer 550 comprises iron and cobalt (e.g., FeCo) or iron and nickel (e.g., FeNi). As noted above the iron containing barrier layer 550 may be chosen in order to minimize the growth of IMC at the interface between the barrier layer 550 and the solder 530. In an embodiment, the solder 530 couples the barrier layer 550 and pad 510 to a die pad 562.

While not shown in FIG. 5A, it is to be appreciated that after one or more reflow or baking operations, an IMC may develop at the interface between the barrier layer 550 and the solder 530. The IMC may be substantially similar to the IMC 225 described in greater detail above with respect to FIG. 2B. That is, an IMC with a thickness of approximately 1 μm or smaller, or approximately 0.5 μm or smaller may be provided between the barrier layer 550 and the solder 530. In an embodiment, the IMC may comprise iron and tin, though other constituents may also be present in the IMC, depending on the composition of the barrier layer 550 and the solder 530.

Referring now to FIG. 5B, a cross-sectional illustration of an electronic package 560 is shown, in accordance with an additional embodiment. In an embodiment, the electronic package 560 may comprise a package substrate 501. In an embodiment, a bridge die 570 may be embedded in the package substrate 501. The bridge die 570 may communicatively couple the first die 561_{A} to the second die 561_{B}. In an embodiment, the bridge die 570 may be coupled to bridge pads 510_{A} by vias 571 or the like. The bridge pads 510_{A} may have a barrier layer 550_{A}. In an embodiment, the barrier layer 550_{A} may be substantially similar to the barrier layer 550 described above with respect to FIG. 5A. That is, the barrier layer 550_{A} may comprise iron, and cobalt or nickel. In an embodiment, a solder 530 couples the bridge pads 510_{A} and the barrier layer 550_{A} to a die pad 562_{A}. While not shown, it is to be appreciated that a barrier layer (e.g., iron-cobalt or iron-nickel) may be provided over the die pads 562_{A} and 562_{B}. In an embodiment, the bridge pads 510_{A} may have a fine pitch, such as a pitch that is approximately 25 μm or smaller.

In an embodiment, the first die 561_{A} and the second die 561_{B} may also be directly coupled to the package substrate by pads 510_{B}. Pads 510_{B} may be larger than the bridge pads 510_{A} and have a larger pitch. However, the pads 510_{B} may also have a barrier layer 550_{B}. The barrier layer 550_{B} may be substantially similar to the barrier layer 550_{A}. Solder 530 may couple the pads 510_{B} and the barrier layer 550_{B} to the die pads 562_{B}.

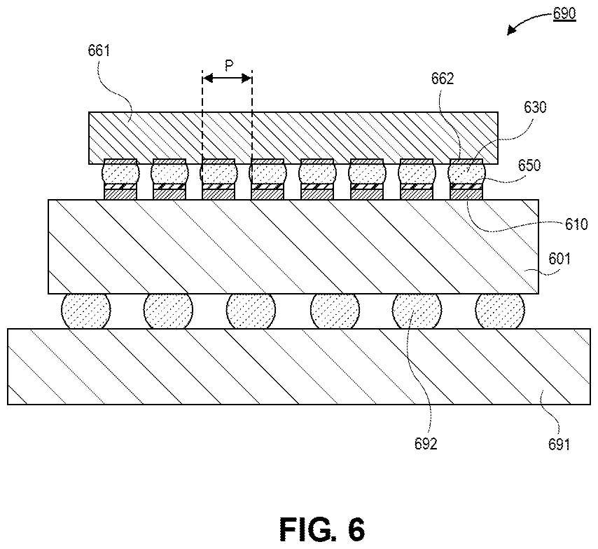

Referring now to FIG. 6, a cross-sectional illustration of an electronic system 690 is shown, in accordance with an embodiment. In an embodiment, the electronic system 690 comprises a board 691, such as a printed circuit board (PCB). In an embodiment, the board 691 is coupled to a package substrate 601 by second level interconnects (SLIs) 692. In the illustrated embodiment, the SLIs 692 are shown as solder balls. However, it is to be appreciated that the SLIs 692 may be any suitable interconnect architecture, such as sockets or the like.

In an embodiment, the package substrate 601 may be an organic package substrate. That is, the package substrate 601 may comprise a plurality of laminated dielectric layers with conductive routing (not shown) embedded therein. The package substrate 601 may also comprise a core, a glass layer, or any other materials typical of electronic packaging architectures.

In an embodiment, a plurality of pads 610 are provided over a surface of the package substrate 601. The pads 610 may be a conductive material. For example, the pads 610 may comprise copper or the like. In an embodiment, the pads 610 are FLI pads. That is, the pads 610 may be used to connect the package substrate 601 to a die 661. In an embodiment, the pads 610 have a fine pitch P. For example, the pitch P may be approximately 25 μm or less.

In an embodiment, a barrier layer 650 is provided over a top surface of the pads 610. In an embodiment, the barrier layer 650 may have a thickness that is approximately 1 μm thick or greater. In an embodiment, the barrier layer 650 may comprise iron. In a particular embodiment, the barrier layer 650 comprises iron and cobalt (e.g., FeCo) or iron and nickel (e.g., FeNi). As noted above the iron containing barrier layer 650 may be chosen in order to minimize the growth of IMC at the interface between the barrier layer 650 and the solder 630. In an embodiment, the solder 630 couples the barrier layer 650 and pad 610 to a die pad 662.

While not shown in FIG. 6, it is to be appreciated that after one or more reflow or baking operations, an IMC may develop at the interface between the barrier layer 650 and the solder 630. The IMC may be substantially similar to the IMC 225 described in greater detail above with respect to FIG. 2B. That is, an IMC with a thickness of approximately 1 μm or smaller, or approximately 0.5 μm or smaller may be provided between the barrier layer 650 and the solder 630. In an embodiment, the IMC may comprise iron and tin, though other constituents may also be present in the IMC, depending on the composition of the barrier layer 650 and the solder 630.

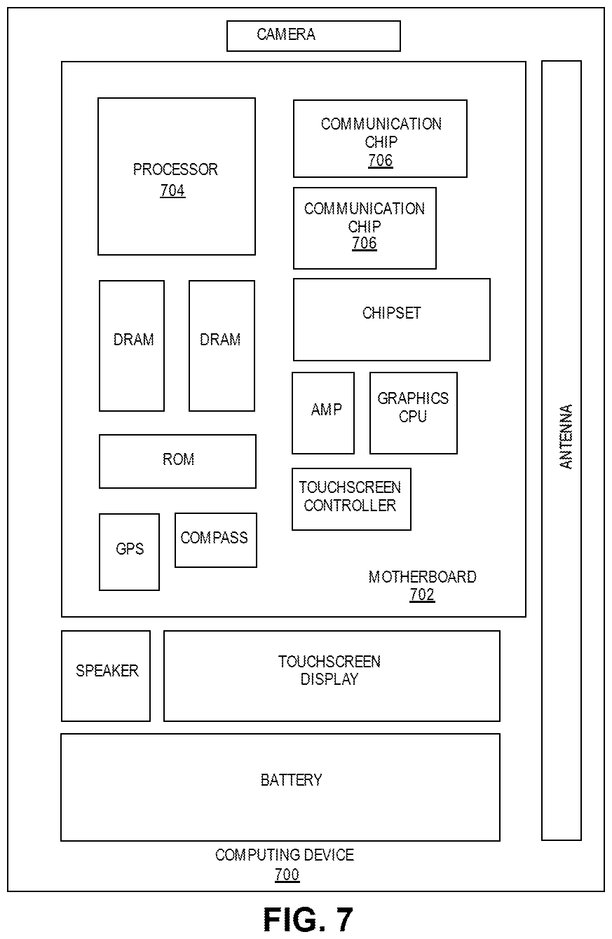

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor may be part of an electronic package that comprises a first level interconnect that comprises a pad and a barrier layer comprising iron and cobalt, or iron and nickel over the pad, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip may be part of an electronic package that comprises a first level interconnect that comprises a pad and a barrier layer comprising iron and cobalt, or iron and nickel over the pad, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a package substrate; a pad on the package substrate, wherein the pad comprises copper; a first layer over the pad, wherein the first layer comprises iron; a solder over the first layer; and a die coupled to the package substrate by the solder.

Example 2: the electronic package of Example 1, wherein the first layer further comprises cobalt, and wherein the first layer is a barrier layer.

Example 3: the electronic package of Example 1, wherein the first layer further comprises nickel, and wherein the first layer is a barrier layer.

Example 4: the electronic package of Examples 1-3, further comprising: an intermetallic compound between the first layer and the solder.

Example 5: the electronic package of Example 4, wherein the intermetallic compound has a thickness that is less than approximately 1 μm.

Example 6: the electronic package of Example 5, wherein the thickness of the intermetallic compound is less than approximately 0.5 μm.

Example 7: the electronic package of Example 4 or Example 5, wherein the intermetallic compound comprises iron and tin.

Example 8: the electronic package of Examples 1-7, further comprising: a second layer over a pad on the die, wherein the second layer comprises iron and cobalt or iron and nickel.

Example 9: the electronic package of Examples 1-8, further comprising: a second pad over the package substrate, wherein the second pad is spaced away from the first pad by a pitch, wherein the pitch is approximately 25 μm or less.

Example 10: the electronic package of Examples 1-9, wherein a thickness of the first layer is approximately 1 μm or thicker.

Example 11: a first level interconnect, comprising: a pad, wherein the pad comprises copper; a first layer over the pad, wherein the first layer comprises iron, and wherein a thickness of the first layer is approximately 1 μm or thicker; and a solder over the first layer.

Example 12: the first level interconnect of Example 11, wherein the solder comprises tin.

Example 13: the first level interconnect of Example 11 or Example 12, wherein the first layer further comprises cobalt.

Example 14: the first level interconnect of Examples 11-13, wherein the first layer further comprises nickel.

Example 15: the first level interconnect of Examples 11-14, further comprising: a layer between the first layer and the solder, wherein the layer comprises an intermetallic compound.

Example 16: the first level interconnect of Example 15, wherein the intermetallic compound comprises iron and tin.

Example 17: the first level interconnect of Example 16, wherein the intermetallic compound comprises FeSn₂.

Example 18: the first level interconnect of Examples 15-17, wherein a thickness of the layer is less than approximately 1 μm.

Example 19: the first level interconnect of Examples 11-18, wherein the first level interconnect couples a package substrate to a die.

Example 20: an electronic system, comprising: a board; a package substrate coupled to the board with second level interconnects; and a die coupled to the package substrate with first level interconnects, wherein individual one of the first level interconnects comprise: a pad; a first layer over the pad, wherein the first layer comprises iron; and a solder over the first layer.

Example 21: the electronic system of Example 20, wherein the first layer further comprises cobalt or nickel.

Example 22: the electronic system of Example 20 or Example 21, wherein the first layer has a thickness that is approximately 2 μm or smaller.

Example 23: the electronic system of Examples 20-22, wherein the first level interconnects comprise a pitch that is approximately 25 μm or smaller.

Example 24: the electronic system of Examples 20-23, further comprising a layer between the first layer and the solder, wherein the layer comprises an intermetallic compound.

Example 25: the electronic system of Example 24, wherein the layer has a thickness that is approximately 1 μm or smaller.

What is claimed is:

1. An electronic package, comprising:
a package substrate;
a pad on the package substrate, wherein the pad comprises copper;
a first layer over the pad, wherein the first layer comprises iron;
a solder over the first layer; and
a die coupled to the package substrate by the solder.

2. The electronic package of claim 1, wherein the first layer further comprises cobalt, and wherein the first layer is a barrier layer.

3. The electronic package of claim 1, wherein the first layer further comprises nickel, and wherein the first layer is a barrier layer.

4. The electronic package of claim 1, further comprising:
an intermetallic compound between the first layer and the solder.

5. The electronic package of claim 4, wherein the intermetallic compound has a thickness that is less than approximately 1 μm.

6. The electronic package of claim 5, wherein the thickness of the intermetallic compound is less than approximately 0.5 μm.

7. The electronic package of claim 4, wherein the intermetallic compound comprises iron and tin.

8. The electronic package of claim 1, further comprising:
a second layer over a pad on the die, wherein the second layer comprises iron and cobalt or iron and nickel.

9. The electronic package of claim 1, further comprising:
a second pad over the package substrate, wherein the second pad is spaced away from the first pad by a pitch, wherein the pitch is approximately 25 μm or less.

10. The electronic package of claim 1, wherein a thickness of the first layer is approximately 1 μm or thicker.

11. A first level interconnect, comprising:
a pad, wherein the pad comprises copper;
a first layer over the pad, wherein the first layer comprises iron, and wherein a thickness of the first layer is approximately 1 μm or thicker; and
a solder over the first layer.

12. The first level interconnect of claim 11, wherein the solder comprises tin.

13. The first level interconnect of claim 11, wherein the first layer further comprises cobalt.

14. The first level interconnect of claim 11, wherein the first layer further comprises nickel.

15. The first level interconnect of claim 11, further comprising:
a layer between the first layer and the solder, wherein the layer comprises an intermetallic compound.

16. The first level interconnect of claim 15, wherein the intermetallic compound comprises iron and tin.

17. The first level interconnect of claim 16, wherein the intermetallic compound comprises FeSn₂.

18. The first level interconnect of claim 15, wherein a thickness of the layer is less than approximately 1 μm.

19. The first level interconnect of claim 11, wherein the first level interconnect couples a package substrate to a die.

20. An electronic system, comprising:
a board;
a package substrate coupled to the board with second level interconnects; and
a die coupled to the package substrate with first level interconnects,
wherein individual one of the first level interconnects comprise:
a pad;
a first layer over the pad, wherein the first layer comprises iron; and
a solder over the first layer.

21. The electronic system of claim 20, wherein the first layer further comprises cobalt or nickel.

22. The electronic system of claim 20, wherein the first layer has a thickness that is approximately 2 μm or smaller.

23. The electronic system of claim 20, wherein the first level interconnects comprise a pitch that is approximately 25 μm or smaller.

24. The electronic system of claim 20, further comprising a layer between the first layer and the solder, wherein the layer comprises an intermetallic compound.

25. The electronic system of claim 24, wherein the layer has a thickness that is approximately 1 μm or smaller.
